(19) United States
(12) Patent Application Publication
(10) Pub. No.: US 2026/0179706 A1
(43) Pub. Date: Jun. 25, 2026

(54) ERROR REDUCTION TECHNIQUES FOR MEMORY SYSTEMS

(71) Applicant: Micron Technology, Inc., Boise, ID (US)

(72) Inventors: Jiao Xiong, Shanghai (CN); Jianying Zhu, Shanghai (CN); Bo Zhou, Shanghai (CN)

(21) Appl. No.: 19/397,650

(22) Filed: Nov. 21, 2025

Related U.S. Application Data
(60) Provisional application No. 63/737,146, filed on Dec. 20, 2024.

(51) Int. Cl. G11C 29/12

(52) U.S. Cl. CPC G11C 29/12005; G11C 2029/1202

(57) ABSTRACT

Methods, systems, and devices for error reduction techniques for memory systems are described. A memory system may perform a first dummy read operation on a block of memory cells. The memory cells of the block may transition to a first state in accordance with performing the first dummy read operation. The memory system may determine whether a threshold is satisfied in response to performing the first dummy read operation, and the threshold may include a duration after performing the first dummy read operation that the memory cells remain in the first state. The memory system may perform a second dummy read operation on a first page of the block of memory cells in response to determining that the threshold is satisfied, and the memory cells remain in the first state in accordance with performing the second dummy read operation.

### CROSS REFERENCE

The present Application for Patent claims priority to U.S. Patent Application No. 63/737,146 by Xiong et al., entitled “ERROR REDUCTION TECHNIQUES FOR MEMORY SYSTEMS,” filed Dec. 20, 2024, which is assigned to the assignee hereof, and which is expressly incorporated by reference in its entirety herein.

### TECHNICAL FIELD

The following relates to one or more systems for memory, including error reduction techniques for memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIG. 1 shows an example of a system that supports error reduction techniques for memory systems in accordance with examples as disclosed herein.

FIG. 2 shows an example of a voltage distribution that supports error reduction techniques for memory systems in accordance with examples as disclosed herein.

FIG. 3 shows examples of scanning algorithms that support error reduction techniques for memory systems in accordance with examples as disclosed herein.

FIG. 4 shows an example of a process that supports error reduction techniques for memory systems in accordance with examples as disclosed herein.

FIG. 5 shows a block diagram of a memory system that supports error reduction techniques for memory systems in accordance with examples as disclosed herein.

FIG. 6 shows a flowchart illustrating a method or methods that support error reduction techniques for memory systems in accordance with examples as disclosed herein.

### DETAILED DESCRIPTION

Some memory systems may include memory cells (e.g., such as not-and (NAND) memory cells) associated with various states (e.g., threshold voltage states), such as a stable state (e.g., an idle state) and a transient state (e.g., an active state). For example, after an access operation, the memory cells may transition from one state to another state, such as the stable state to the transient state. After remaining idle for a duration (e.g., an extended duration, a relatively long duration), the memory cells may return (e.g., revert, transition back) to the stable state. In some cases, reading data from memory cells in the stable state may result in increased bit error rates (BERs). For instance, one or more threshold voltage distributions may be different (e.g., may have shifted) based on the state of the memory cells (e.g., transient or stable). Moreover, the threshold voltages used for detecting (e.g., sensing) a stored logic state may be configured for (e.g., calibrated to, tuned to) memory cells in the transient state. Thus, performing a read operation before the cells have fully transitioned to the transient state may result in an increased quantity of errors and thus be otherwise undesirable.

In accordance with one or more techniques described herein, a memory system may be configured to periodically (e.g., systematically) perform one or more dummy read operations (e.g., in the background) to maintain memory cells in a transient state. For example, a dummy read operation may refer to a type of read operation where memory cells are read (e.g., sensed), but the associated data is not transmitted to a host system. That is, a dummy read operation may not be associated with a read command received from a host system. In some examples, the memory system may define a threshold duration (e.g., a configured interval) at which a set of dummy read operations is performed for a block of memory cells. In some examples, the dummy read operations may be performed on a first page of a block, which may maintain each of the memory cells of the block in the transient state (e.g., including cells associated with other pages of the block). Thus, by performing the dummy read operations in accordance with the duration, the memory cells may be maintained in the transient state. That is, data of the memory system may be read with increased reliability (e.g., with fewer bit errors) and reduced latency, which may improve overall memory system performance, among other benefits.

In addition to applicability in memory systems as described herein, techniques for error reduction techniques for memory systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by maintaining the NAND memory cells in the transient state, which may reduce data errors, improve reliability, decrease latency, improve response times, or otherwise improve user experience, among other benefits.

Features of the disclosure are illustrated and described in the context of systems, devices, and circuits. Features of the disclosure are further illustrated and described in the context of voltage distributions, scanning algorithms, processes, and flowcharts.

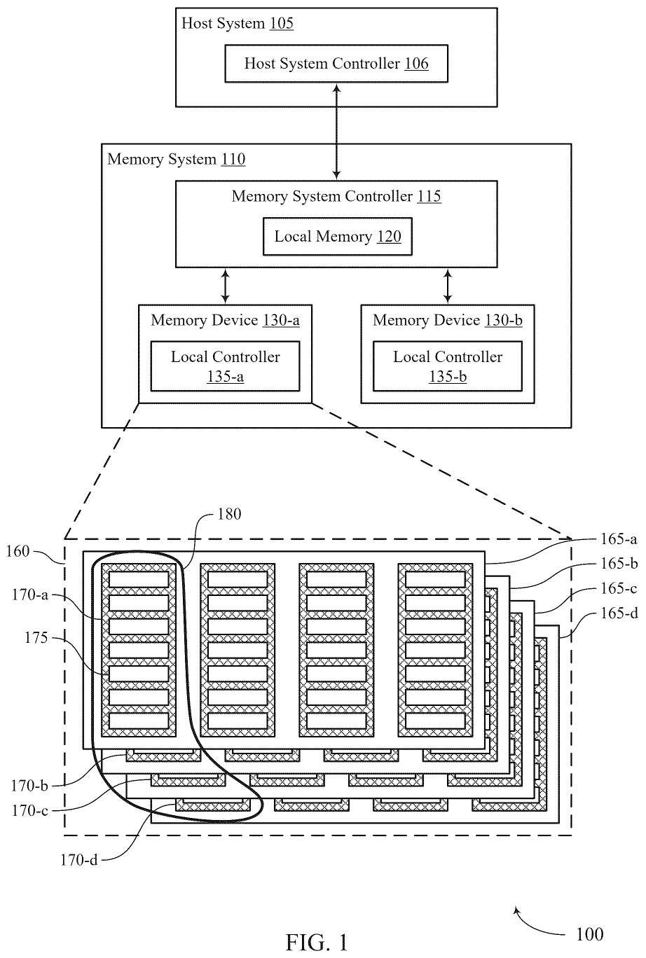

FIG. 1 shows an example of a system 100 that supports error reduction techniques for memory systems in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

Some memory systems 110 may include NAND memory cells associated with various states (e.g., threshold voltage states), such as a stable state and a transient state. For instance, after a read operation, the memory cells may transition from the stable state to the transient state. After remaining idle for an extended duration, the memory cells may return (e.g., revert, transition back) to the stable state. In some cases, reading data from memory cells in the stable state may result in increased BERs during a read operation. For instance, one or more threshold voltage distributions (e.g., associated with a set of logic states) may be different (e.g., shifted) depending on the state of the memory cells (e.g., transient or stable). Moreover, the threshold voltages used for detecting (e.g., sensing) a stored logic state may be configured (e.g., calibrated, tuned) for memory cells in the transient state. Thus, performing a read operation before the cells have fully transitioned to the transient state may result in an increased quantity of errors.

In accordance with one or more techniques described herein, a memory system 110 (e.g., a memory system controller 115, a memory device 130, a local controller 135) may be configured to perform one or more dummy read operations (e.g., in the background, a read operation with relatively lower latency than a host read operation) to maintain memory cells in a transient state. For example, a dummy read operation may refer to a type of read operation where memory cells are read (e.g., sensed) but the associated data is not transmitted to a host system. That is, a dummy read operation may not be associated with a read command received from a host system. In some examples, the memory system 110 may define a threshold duration (e.g., three hours) at which a set of dummy read operations is performed for a block 170 of memory cells. In some examples, the dummy read operations may be performed on a first page 175 of a block 170, which may maintain each of the memory cells of the block 170 in the transient state (e.g., including cells associated with other pages 175 of the block). Thus, by performing the dummy read operations in accordance with the duration, the memory cells may be maintained in the transient state, resulting in relatively fewer errors, reduced latency, and improved overall performance of the system 100.

The system 100 may include any quantity of non-transitory computer readable media that support error reduction techniques for memory systems. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

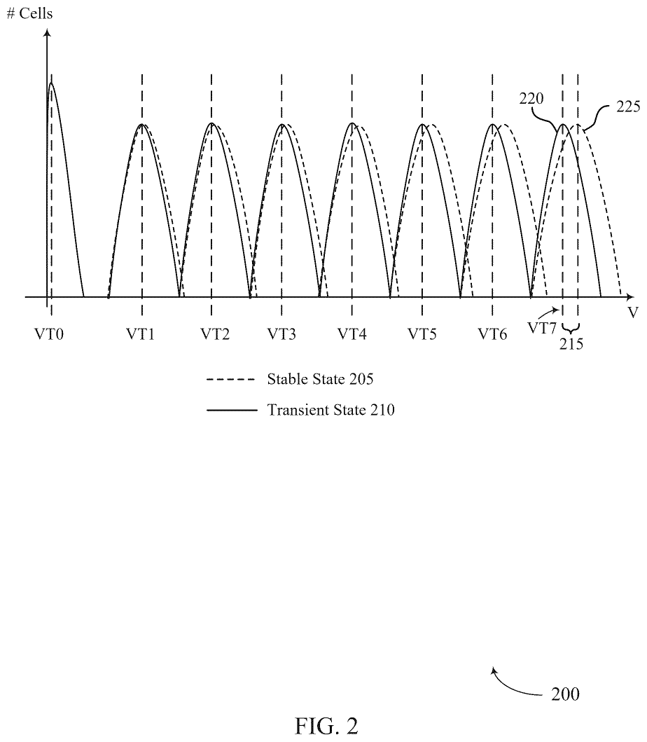

FIG. 2 shows an example of a threshold voltage (VT) distribution 200 that supports error reduction techniques for memory systems in accordance with examples as disclosed herein. The VT distribution 200 may incorporate or may be implemented by one or more aspects of the system 100 as described with reference to FIG. 1. For example, a memory system 110 may implement NAND memory cells (e.g., NAND blocks, blocks 170), and the VT distribution 200 may be associated with a logic state (e.g., detecting a logic state) stored by a NAND memory cell.

The VT distribution 200 may represent a set of VT distributions for TLCs, where a TLC refers to a memory cell that is configured to store three bits of data using one of eight VT levels supported by the memory system (e.g., by a memory system 110). Each of the VT distributions may correspond to a respective logic state, and may be associated with a respective voltage (e.g., a nominal voltage, a nominal threshold voltage, a target voltage, a nominal VT, an average VT). Thus, for the example of implementing TLCs, the VT distribution 200 may include eight VT distributions each associated with a respective voltage (e.g., eight nominal voltages, eight VT levels, labeled VT0 through VT7).

Each nominal VT level may be associated with (e.g., correspond to, represent, store) a respective logic state (e.g., a multi-bit logic state, a 3-bit logic value for TLCs, a multi-bit value). For example, VT0 and its VT distribution may be associated with logic “111”, VT1 and its VT distribution may be associated with logic “110”, and so on. The VT distribution for a nominal VT level may be generally centered around the nominal VT level (e.g., the nominal VT level may be an average voltage for the VT distribution), and the VT distribution 200 may be illustrative of relative quantities of memory cells at various values of threshold voltage (e.g., among a population of memory cells, which may be written with a normalized distribution of, such as equal quantities of, the logic states).

Although described with reference to TLCs, the techniques described herein can be implemented using any type of threshold-voltage based memory cell, including SLCs that are configured to store a single bit in accordance with one of two threshold voltage levels (e.g., two nominal voltages), MLCs that are configured to store two bits in accordance with one of four threshold voltage levels (e.g., four nominal voltages), and QLCs that are configured to store four bits in accordance with one of sixteen threshold voltage levels (e.g., sixteen nominal voltages), and so on.

In some cases (e.g., for three-dimensional (3D) NAND), a memory cell (e.g., NAND cell) may transition (e.g., transfer) between a stable state 205 and a transient state 210 based on an access operation (e.g., a read operation) performed on at least one page of a block of memory cells. In such cases, a first page read (FPR) effect may be observed, where a relatively higher bit error count (BEC) occurs during a first read on a block (e.g., NAND block) in a stable state 205 (e.g., left idle). As used herein, a “stable state” may refer to a default state of a memory cell (e.g., a programmed 3D NAND cell). For instance, a programmed memory cell may return to the stable state 205 if left idle (e.g., for a duration, 3 hours). The increased BEC may occur due to a read window budget (RWB) being configured (e.g., set, optimized) for a transient state 210 (e.g., the distribution of voltages of cells in the 210 may be unshifted), and the stable state 205 may be associated with a shift 215 in the VT, resulting in a relatively higher raw bit error rate (RBER) in the stable state 205.

As used herein, a “transient state” may refer to a temporary state of a memory cell (e.g., a programmed 3D NAND cell). The transient state 210 may have an improved RBER (e.g., relatively lower BEC than the stable state 205) due to the VTs (e.g., nominal VT levels) and/or RWBs being configured (e.g., tuned, calibrated) for the transient state 210. For instance, a logic state associated with VT7 (e.g., a nominal voltage for an eighth logic state) may have a voltage distribution 220 in the transient state 210 and a voltage distribution 225 in the stable state 205. The voltage distribution 225 may be associated with a shift 215 relative to the voltage distribution 220, which may cause a memory system to inaccurately detect the logic state of a memory cell (e.g., leading to one or more bit errors). In some cases, memory cells may begin to transition to the transient state 210 after a single read (e.g., of a single page of the NAND cell). Moreover, one or more cells may remain in the transient state 210 with consecutive reads to the block of NAND cells (e.g., a target block).

In some cases, a FPR effect may reduce bit errors (e.g., a BEC may recover to normal level) by introducing a delay (e.g., 1 second) between a FPR and a following read, however some techniques may not allow a block to transition (e.g., fully transition) the transient state 210 (e.g., associated with relatively low BEC or RBER). Additionally, if a block is not accessed (e.g., remains idle) for a relatively long time (e.g., greater than 3 hours), the block may return to the stable state 205 (e.g., associated with relatively high BEC or RBER), and a system (e.g., a system 100) may experience increased errors (e.g., increased RBER). Some systems may attempt to mitigate the errors based on various scanning algorithms, such as block family error avoidance (BFEA) scans, read disturb scans, and other media scans. However, such methods may not include a sufficient delay to allow the NAND blocks to transition to the transient state 210.

For example, a NAND block may transition to the transient state 210 in accordance with a first duration (e.g., 1 second) after a FRP and the previously described algorithms may include a delay that is shorter than the first duration (e.g., may be 10 milliseconds (ms) or 40 ms). Accordingly, a system may continue to experience the bit error effects, induce an incorrect scanning algorithm, and may experience system over-refresh. Moreover, as lithography techniques advance and programming durations (e.g., tProg) decrease, a base RBER may also increase, thus increasing an overall FPR impact to a memory system.

Additionally, in some cases, a host read (e.g., a read operation that is initiated by a host system 105) may not include techniques to mitigate bit errors associated with a FPR (e.g., or may use a method that is not sufficiently effective as described). Accordingly, some systems may have a relatively high read recovery trigger rate, which may increase read latency. In some examples, a read that is performed after a threshold duration (e.g., 10 seconds to 3 hours) may achieve a target error reduction (e.g., a lowest RBER, may ensure the NAND block is in a transient state 210). As such, techniques may be desired that allow a NAND block to full transition to the transient state 210 prior to reading data from the memory cells.

In accordance with techniques described herein, a memory system (e.g., a memory system 110, a memory system controller 115) may be configured to periodically (e.g., systematically) perform one or more dummy read operations (e.g., one or more sets of dummy read operations) to maintain the blocks (e.g., NAND blocks) of the memory system in a transient state 210. For example, the memory system may perform an FPR scan on each block at a configured periodicity (e.g., once every 3 hours). Such techniques may improve system performance without affecting the latency of the memory system (e.g., and may reduce a risk of over-refresh).

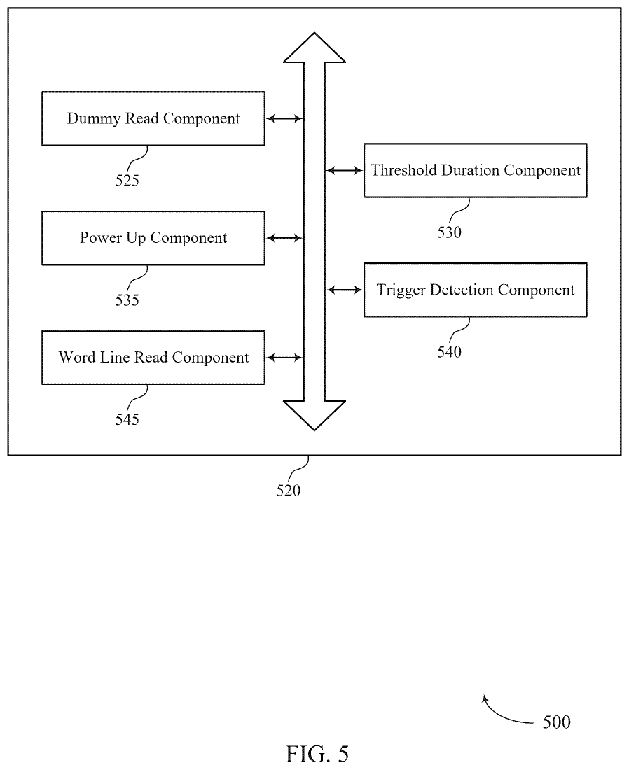

In some examples, the memory system may allocate full sets of dummy read by updating (e.g., reconfiguring, modifying) one or more system scan techniques (e.g., as described in greater detail herein, including with reference to FIG. 5) by inserting additional dummy reads with relatively short latency (e.g., shorter than a threshold), or by some other technique described herein. A set of dummy read operations may, in some examples, include performing a dummy read on one or more blocks (e.g., each block, blocks 170) of one or more planes (e.g., each plane, planes 165) of one or more dies (e.g., each die, dies 160) of a memory system. In some examples, a latency of a full set of dummy read operations may be less than a threshold (e.g., less than 10 ms). In some examples, a dummy read operation on a block may include reading one or more pages (e.g., one page, an edge SLC page, pages 175).

By executing dummy read operations in accordance with a defined interval (e.g., based on satisfying a threshold duration), a memory system may reduce latency by omitting other read operations associated with other media scans, BFEA scans, and read disturb scans (e.g., which may be associated with higher latency, such as 40 ms or 10 ms per dummy read). For example, a BFEA scan, a media scan, or a read disturb scan may use read operations that are each associated with a first duration (e.g., 40 ms), and the periodic dummy read operations described herein may be associated with a second duration (e.g., 22 microseconds (μs)) that is less than the first duration.

In some examples, an initial power up procedure (e.g., power up scan, power up algorithm) may implement one or more techniques herein. For example, a conventional power up procedure (e.g., a two-times BFEA scan) may include a first BFEA scan that covers a first block type and a second block type (e.g., BIN0 and BIN1 blocks, associated with a single plane), which may be associated with a first duration (e.g., a latency, 719 ms), and may include a second BFEA scan on the first and second block types (e.g., may not transition other blocks to transient state 210). Alternatively, using the techniques herein, a power up procedure may utilize a full set of dummy read operations to cover each block of the system prior to a BFEA scan. For example, a full set of dummy read operations may be followed by a delay (e.g., 30.5 ms), and the read operations plus the delay may be associated with a second duration (e.g., 40 ms) that is less than the first duration. After the delay, the power up procedure may then perform the BFEA scan (e.g., on BIN0 and BIN1 blocks). Such examples may ensure that each of the blocks transition to the transient state 210 and may be associated with a reduced latency.

In some examples, performing periodic dummy read operations may reduce the system's latency. For example, if the memory system receives a host read command during a performance of a dummy read, a latency (e.g., speed drop) may be relatively small (e.g., smaller than a threshold). Moreover, in some examples, the memory system may allocate (e.g., configure) the full dummy read operations to be performed in the background, and one or more trigger conditions (e.g., defined, set, or programmed, by the memory system) may be used to reduce (e.g., cancel, stop, mitigate) the performance impact of one or more dummy read operations (e.g., to decrease an influence of the dummy read performance on the memory system). In some examples, the one or more trigger conditions may include a duration (e.g., different than the threshold duration used for triggering the dummy read operations), a performance of one or more other tasks by the memory system, receiving a host command (e.g., host read, host write), or a combination thereof. Accordingly, the techniques described herein may reduce the system's latency and improve its overall performance.

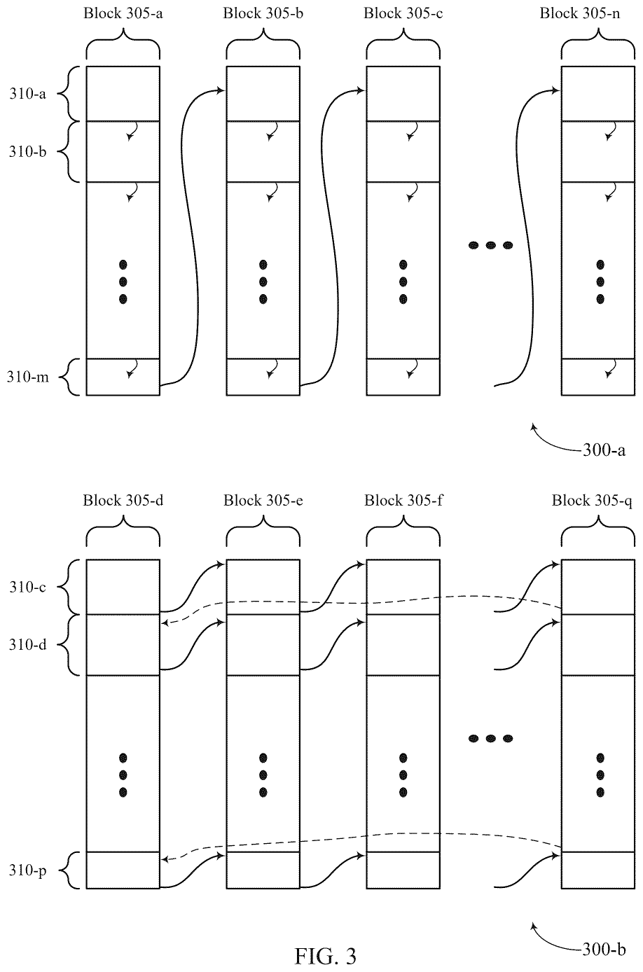

FIG. 3 shows examples of scanning algorithms 300 that support error reduction techniques for memory systems in accordance with examples as disclosed herein. The scanning algorithms 300 may implement or be implemented by one or more aspects of the system 100 and the VT distribution 200 as described with reference to FIGS. 1 and 2. For example, a memory system 110 may implement a scanning algorithm 300-b to reduce bit errors during read operations by maintain blocks of memory cells (e.g., NAND memory cells) in a transient state 210.

The scanning algorithms 300 may illustrate an array that includes multiple blocks 305 (e.g., NAND blocks, block of non-volatile memory), and each block 305 may include multiple word lines 310. For example, the scanning algorithm 300-a may include a block 305-a, a block 305-b, a block 305-c, and up to block 305-n, and a word line 310-a, a word line 310-b, up to word line 310-m. The scanning algorithm 300-b may include a block 305-d, a block 305-e, a block 305-f, up to block 305-q, and a word line 310-c, a word line 310-d, up to word line 310-p. The techniques herein may be applied to any quantity of blocks 305 and any quantity of word lines 310, include more or fewer than shown in the example of FIG. 3.

In some cases, a scanning algorithm 300-a may illustrate a scan mode that scans (e.g., performs a dummy read operation for) the array block-by-block. For example, the scanning algorithm 300-a may begin scanning at the block 305-a and the word line 310-a. After scanning the word line 310-a of the block 305-a, the algorithm may proceed to scan the word line 310-b of the block 305-a. The pattern may be repeated such that each word line 310 of the block 305-a is scanned before the algorithm proceeds to scan the word lines 310 of the block 305-b. A similar pattern may be followed until each of the word lines 310 of each block 305 is scanned (e.g., up to the word line 310-m of the block 305-n). However, such an approach may activate one block 305 at a time, thus leaving each block 305 idle for a duration (e.g., and each block may begin a transition to a stable state 205). That is, the scanning algorithm 300-a may be relatively more susceptible to bit errors due to a relatively longer duration between access operations on a given block 305 (e.g., may not maintain the blocks 305 in a transient state 210).

To improve performance of a system and reduce bit errors, a memory system may support the scanning algorithm 300-b. The scanning algorithm 300-b may support a scan mode that scans the array word line-by-word line, which may reduce a duration between access operations of each block 305 (e.g., thus maintaining the blocks 305 in the transient state 210). For example, the scanning algorithm 300-b may begin scanning at the block 305-d and the word line 310-c (e.g., a first mandatory word line). After scanning the word line 310-c of the block 305-d, the algorithm may proceed to scan the word line 310-c of the block 305-e. The pattern may be repeated such that the word line 310-c of each block 305 is scanned, after which the algorithm may proceed to scan the word line 310-d (e.g., a second mandatory word line) of each block 305. A similar pattern may be followed (e.g., moving from the block 305-d to the block 305-e, and so on) until each word lines 310 of each block 305 is scanned (e.g., up to the word line 310-p of the block 305-q).

Accordingly, such techniques may enable a foreground media scan to more effectively mitigate bit errors during read operations (e.g., mitigate a FPR effect). For example, the scanning algorithm 300-b may increase a quantity of activations of a given block 305, which may maintain each of the memory cells (e.g., of each word line 310) in the transient state 210 that is associate with relatively fewer bit errors.

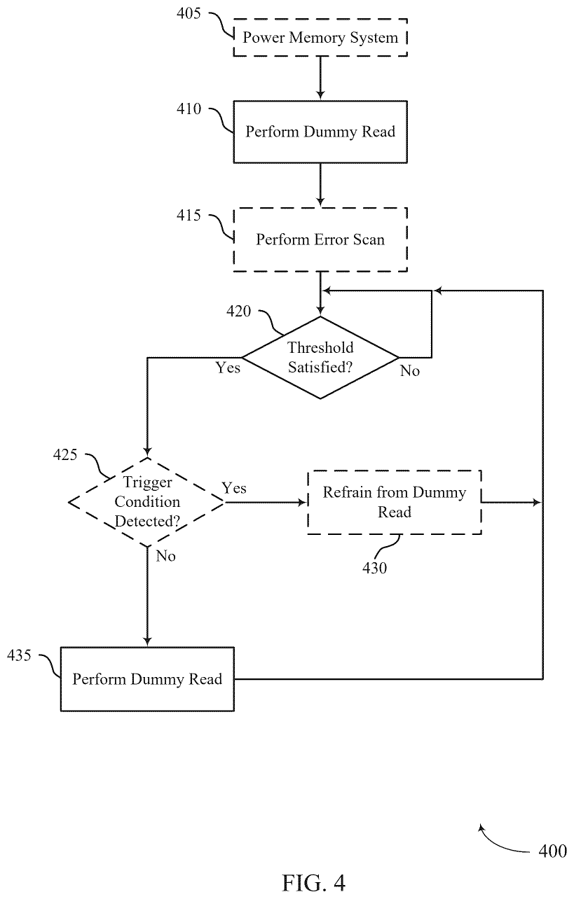

FIG. 4 shows an example of a process 400 that supports error reduction techniques for memory systems in accordance with examples as disclosed herein. Aspects of the process 400 may be implemented by one or more controllers, among other components. Additionally, or alternatively, aspects of the process 400 may be implemented as instructions stored in one or more memories (e.g., firmware stored in one or more memories coupled with a memory system 110). For example, the instructions, when executed by one or more controllers (e.g., the memory system controller 115), may cause the one or more controllers (or a device or a system) to perform the operations of the process 400. Alternative examples of the following may be implemented. For example, some steps may be performed in a different order than described or may not be performed at all. In some implementations, steps may include additional features not mentioned below, or further steps may be added.

At 405, in some examples, a memory system (e.g., a memory system 110) may be powered up (e.g., booted, initialized). In response to powering up, the memory system may support a initialization of one or more blocks of memory cells in accordance with techniques described herein.

At 410, a dummy read operation may be performed. For example, the memory system may perform a dummy read operation on a block (e.g., block 170, block 305) of memory cells (e.g., NAND memory cells). In some examples, the memory cells of the block may transition to a first state (e.g., a transient state 210, from a stable state 205 to the transient state 210) in accordance with performing the dummy read operation. In some examples, the memory system may perform the dummy read operation in response to (e.g., based on, after) powering the memory system.

In some examples, the dummy read operation may be performed on each first page (e.g., a page 175, an edge SLC page) of a set of multiple of blocks of memory cells included in the memory system. In some examples, each of the memory cells of the blocks may transition to the first state. In some examples, the memory cells of the memory system may include non-volatile memory cells (e.g., NAND cells), each non-volatile memory cell associated with one of a set of multiple of logical pages (e.g., an edge SLC page, a lower page (LP), an upper page (UP), an extra page (XP), and a top page (TP)) that includes the first page (e.g., an edge SLC page, or other page). In some examples, the read operation performed at 410 may be a normal read operation (e.g., a first read operation performed by the memory system).

In some examples, the first state may correspond to a transient state (e.g., the transient state 210) for which a threshold voltage distribution for one or more memory cells is unshifted relative to a target threshold voltage distribution (e.g., relative to target VTs or tuned VTs) used for reading the one or more memory cells. In some examples, the memory cells of the block may be in a second state prior to performing the dummy read operation. In some examples, the second state may correspond to a stable state (e.g., a stable state 205) for which a threshold voltage distribution for one or more memory cells is shifted (e.g., in accordance with a shift 215) relative to the target threshold voltage distribution.

In some examples, a dummy read operation may be associated with reading data from one or more memory cells and refraining from outputting the data (e.g., to a host system 105). In some examples, the memory system may perform one or more normal read operations (e.g., at any point in the process 400), which may be based on a host command or an internal command (e.g., an internal firmware command). In some examples, a normal read operation may be associated with reading data from the one or more memory cells and outputting the data (e.g., to the host system).

At 415, in some examples, an error scan operation may be performed. For example, the memory system may perform an error scan operation (e.g., a BFEA scan) on a subset of blocks (e.g., BIN0 and/or BIN1 blocks) of the multiple blocks after performing the dummy read operation and prior to performing other dummy read operations. In some examples, the error scan operation may be performed based on powering up the memory system (e.g., may be part of a power up sequence).

At 420, it may be determined whether a threshold is satisfied. For example, the memory system may determine whether a threshold is satisfied in response to performing the dummy read operation. In some examples, the threshold may be associated with a duration that the memory cells remain in the first state after performing the dummy read operation (e.g., a duration less than or equal to 3 hours, a duration with a value between 1 second and 3 hours, such as 10 seconds). If the threshold is satisfied, the process may continue to 425 and may return to 420 otherwise. That is, the memory system may wait until the threshold duration is satisfied before performing additional dummy read operations.

At 425, in some examples, one or more trigger conditions may be detected. For example, the memory system may detect one or more trigger conditions for reducing dummy read operations. In some examples, such trigger condition detection may occur at any point in the process 400 (e.g., may interrupt some other step, the memory system may constantly monitor the one or more trigger conditions). In some examples, the one or more trigger conditions may include a duration (e.g., different than the threshold duration used for triggering the dummy read operations), a performance of one or more other tasks (e.g., read operations, write operations, memory management operations, garbage collection operations, refresh operations, or other tasks) by the memory system, receiving a host command (e.g., host read, host write, or other host signaling), or a combination thereof. If one or more trigger conditions are detected, the process may proceed to 435 and may proceed to 430 otherwise.

At 430, in some examples, a dummy read operation may be refrained from being performed. For example, the memory system may refrain from performing a dummy read operation on the block in response to detecting the one or more trigger conditions. Such techniques may reduce a quantity of dummy read operations (e.g., in order to improve performance of one or more other aspects of the memory system).

At 435, a dummy read operation may be performed. For example, the memory system may perform a second dummy read operation (e.g., a subsequent dummy read operation) on a first page of the block of memory cells in response to determining that the threshold is satisfied (e.g., and in the absence of a trigger condition). In some examples, the memory cells may remain in the first state in accordance with performing the second dummy read operation. In some examples, the second read operation may include performing the second dummy read operation on the set of multiple of blocks of memory cells including the block, and the memory cells of each block may remain in the first state in accordance with performing the second dummy read operation. In some examples (e.g., in accordance with a scanning algorithm 300-b), performing the dummy read operation may include reading a first word line (e.g., the word line 310-c) of the block. The memory system may read, after reading the first word line of the block, a first word line of each other block of the multiple blocks in sequence (e.g., sequentially). The memory system may then read a second word line (e.g., the word line 310-d) of the block after reading each first word line of the multiple blocks.

In some examples, after performing the one or more dummy read operations, the process may return to 420 to monitor for the next occurrence that the threshold is satisfied. For example, the process may return to 420, and the memory system may determine whether the threshold is satisfied for a second occurrence after performing the second dummy read operation. Accordingly, in some examples, the memory system performing a third dummy read operation on the first page of the block in response to determining that the threshold is satisfied for the second occurrence, and the memory cells remain in the first state in accordance with performing the third dummy read operation. That is, the process 400 may support a continuous process that maintains (e.g., at a consistent periodicity) the memory cells of one or more blocks of the memory system in the transient state, resulting in reduced bit errors, improved system performance, reduced latency, and other benefits.

FIG. 5 shows a block diagram 500 of a memory system 520 that supports error reduction techniques for memory systems in accordance with examples as disclosed herein. The memory system 520 may be an example of aspects of a memory system as described with reference to FIGS. 1 through 3. The memory system 520, or various components thereof, may be an example of means for performing various aspects of error reduction techniques for memory systems as described herein. For example, the memory system 520 may include a dummy read component 525, a threshold duration component 530, a power up component 535, a trigger detection component 540, a word line read component 545, or any combination thereof. Each of these components, or components of subcomponents thereof (e.g., one or more processors, one or more memories), may communicate, directly or indirectly, with one another (e.g., via one or more buses).

The dummy read component 525 may be configured as or otherwise support a means for performing a first dummy read operation on a block of memory cells, where the memory cells of the block transition to a first state in accordance with performing the first dummy read operation. The threshold duration component 530 may be configured as or otherwise support a means for determining whether a threshold is satisfied in response to performing the first dummy read operation, where the threshold includes a duration after performing the first dummy read operation that the memory cells remain in the first state. In some examples, the dummy read component 525 may be configured as or otherwise support a means for performing a second dummy read operation on a first page of the block of memory cells in response to determining that the threshold is satisfied, where the memory cells remain in the first state in accordance with performing the second dummy read operation.

In some examples, a dummy read operation is associated with reading data from one or more memory cells and refraining from outputting the data (e.g., to a host system). In some examples, a normal read operation is associated with reading data from the one or more memory cells and outputting the data (e.g., to the host system).

In some examples, the first state corresponds to a transient state for which a threshold voltage distribution for one or more memory cells is unshifted relative to a target threshold voltage distribution used for reading the one or more memory cells. In some examples, the memory cells of the block are in a second state prior to performing the first dummy read operation. In some examples, the second state corresponds to a stable state for which a threshold voltage distribution for one or more memory cells is shifted relative to the target threshold voltage distribution.

In some examples, the threshold duration component 530 may be configured as or otherwise support a means for determining whether the threshold is satisfied for a second occurrence after performing the second dummy read operation. In some examples, the dummy read component 525 may be configured as or otherwise support a means for performing a third dummy read operation on the first page of the block in response to determining that the threshold is satisfied for the second occurrence, where the memory cells remain in the first state in accordance with performing the third dummy read operation.

In some examples, to support performing the second dummy read operation, the dummy read component 525 may be configured as or otherwise support a means for performing the second dummy read operation on a plurality of blocks of memory cells including the block, where the memory cells of each block remain in the first state in accordance with performing the second dummy read operation.

In some examples, to support performing the second dummy read operation on the plurality of blocks, the word line read component 545 may be configured as or otherwise support a means for reading a first word line of the block. In some examples, to support performing the second dummy read operation on the plurality of blocks, the word line read component 545 may be configured as or otherwise support a means for reading, after reading the first word line of the block, a first word line of each other block of the plurality of blocks in sequence. In some examples, to support performing the second dummy read operation on the plurality of blocks, the word line read component 545 may be configured as or otherwise support a means for reading a second word line of the block after reading each first word line of the plurality of blocks.

In some examples, the power up component 535 may be configured as or otherwise support a means for performing, in response to powering the memory system, a third dummy read operation on each first page of a plurality of blocks of memory cells including the block, where each of the memory cells of the block transitions to the first state in accordance with performing the third dummy read operation. In some examples, the power up component 535 may be configured as or otherwise support a means for performing an error scan operation on a subset of blocks of the plurality of blocks after performing the third dummy read operation and prior to performing the first dummy read operation.

In some examples, the trigger detection component 540 may be configured as or otherwise support a means for detecting one or more trigger conditions for reducing dummy read operations. In some examples, the trigger detection component 540 may be configured as or otherwise support a means for refraining from performing a third dummy read operation on the block in response to detecting the one or more trigger conditions.

In some examples, the memory cells include non-volatile memory cells, each non-volatile memory cell associated with one of a plurality of logical pages that includes the first page.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

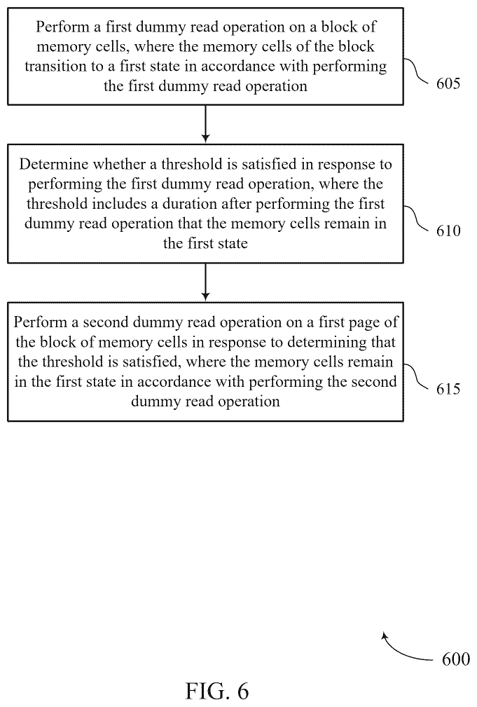

FIG. 6 shows a flowchart illustrating a method 600 that supports error reduction techniques for memory systems in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include performing a first dummy read operation on a block of memory cells, where the memory cells of the block transition to a first state in accordance with performing the first dummy read operation. In some examples, aspects of the operations of 605 may be performed by a dummy read component 525 as described with reference to FIG. 5.

At 610, the method may include determining whether a threshold is satisfied in response to performing the first dummy read operation, where the threshold includes a duration after performing the first dummy read operation that the memory cells remain in the first state. In some examples, aspects of the operations of 610 may be performed by a threshold duration component 530 as described with reference to FIG. 5.

At 615, the method may include performing a second dummy read operation on a first page of the block of memory cells in response to determining that the threshold is satisfied, where the memory cells remain in the first state in accordance with performing the second dummy read operation. In some examples, aspects of the operations of 615 may be performed by a dummy read component 525 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for performing a first dummy read operation on a block of memory cells, where the memory cells of the block transition to a first state in accordance with performing the first dummy read operation; determining whether a threshold is satisfied in response to performing the first dummy read operation, where the threshold includes a duration after performing the first dummy read operation that the memory cells remain in the first state; and performing a second dummy read operation on a first page of the block of memory cells in response to determining that the threshold is satisfied, where the memory cells remain in the first state in accordance with performing the second dummy read operation.
Aspect 2: The method, apparatus, or non-transitory computer-readable medium of aspect 1, where a dummy read operation is associated with reading data from one or more memory cells and refraining from outputting the data and a normal read operation is associated with reading data from the one or more memory cells and outputting the data.
Aspect 3: The method, apparatus, or non-transitory computer-readable medium of any of aspects 1 through 2, where the first state corresponds to a transient state for which a threshold voltage distribution for one or more memory cells is unshifted relative to a target threshold voltage distribution used for reading the one or more memory cells; the memory cells of the block are in a second state prior to performing the first dummy read operation; and the second state corresponds to a stable state for which a threshold voltage distribution for one or more memory cells is shifted relative to the target threshold voltage distribution.
Aspect 4: The method, apparatus, or non-transitory computer-readable medium of any of aspects 1 through 3, further including operations, features, circuitry, logic, means, or instructions, or any combination thereof for determining whether the threshold is satisfied for a second occurrence after performing the second dummy read operation and performing a third dummy read operation on the first page of the block in response to determining that the threshold is satisfied for the second occurrence, where the memory cells remain in the first state in accordance with performing the third dummy read operation.
Aspect 5: The method, apparatus, or non-transitory computer-readable medium of any of aspect s1 through 4, where performing the second dummy read operation includes operations, features, circuitry, logic, means, or instructions, or any combination thereof for performing the second dummy read operation on a plurality of blocks of memory cells including the block, where the memory cells of each block remain in the first state in accordance with performing the second dummy read operation.
Aspect 6: The method, apparatus, or non-transitory computer-readable medium of aspect 5, where performing the second dummy read operation on the plurality of blocks includes operations, features, circuitry, logic, means, or instructions, or any combination thereof for reading a first word line of the block; reading, after reading the first word line of the block, a first word line of each other block of the plurality of blocks in sequence; and reading a second word line of the block after reading each first word line of the plurality of blocks.
Aspect 7: The method, apparatus, or non-transitory computer-readable medium of any of aspects 1 through 6, further including operations, features, circuitry, logic, means, or instructions, or any combination thereof for performing, in response to powering the memory system, a third dummy read operation on each first page of a plurality of blocks of memory cells including the block, where each of the memory cells of the block transitions to the first state in accordance with performing the third dummy read operation and performing an error scan operation on a subset of blocks of the plurality of blocks after performing the third dummy read operation and prior to performing the first dummy read operation.
Aspect 8: The method, apparatus, or non-transitory computer-readable medium of any of aspects 1 through 7, further including operations, features, circuitry, logic, means, or instructions, or any combination thereof for detecting one or more trigger conditions for reducing dummy read operations and refraining from performing a third dummy read operation on the block in response to detecting the one or more trigger conditions.
Aspect 9: The method, apparatus, or non-transitory computer-readable medium of any of aspects 1 through 8, where the memory cells include non-volatile memory cells, each non-volatile memory cell associated with one of a plurality of logical pages that includes the first page.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
perform a first dummy read operation on a block of memory cells, wherein the memory cells of the block transition to a first state in accordance with performing the first dummy read operation;
determine whether a threshold is satisfied in response to performing the first dummy read operation, wherein the threshold comprises a duration after performing the first dummy read operation that the memory cells remain in the first state; and
perform a second dummy read operation on a first page of the block of memory cells in response to determining that the threshold is satisfied, wherein the memory cells remain in the first state in accordance with performing the second dummy read operation.

2. The memory system of claim 1, wherein:
a dummy read operation is associated with reading data from one or more memory cells and refraining from outputting the data; and
a normal read operation is associated with reading data from the one or more memory cells and outputting the data.

3. The memory system of claim 1, wherein:
the first state corresponds to a transient state for which a threshold voltage distribution for one or more memory cells is unshifted relative to a target threshold voltage distribution used for reading the one or more memory cells;
the memory cells of the block are in a second state prior to performing the first dummy read operation; and
the second state corresponds to a stable state for which a threshold voltage distribution for one or more memory cells is shifted relative to the target threshold voltage distribution.

4. The memory system of claim 1, wherein the processing circuitry is further configured to cause the memory system to:
determine whether the threshold is satisfied for a second occurrence after performing the second dummy read operation; and
perform a third dummy read operation on the first page of the block in response to determining that the threshold is satisfied for the second occurrence, wherein the memory cells remain in the first state in accordance with performing the third dummy read operation.

5. The memory system of claim 1, wherein, to perform the second dummy read operation, the processing circuitry is configured to cause the memory system to:
perform the second dummy read operation on a plurality of blocks of memory cells including the block, wherein the memory cells of each block remain in the first state in accordance with performing the second dummy read operation.

6. The memory system of claim 5, wherein, to perform the second dummy read operation on the plurality of blocks, the processing circuitry is configured to cause the memory system to:
read a first word line of the block;
read, after reading the first word line of the block, a first word line of each other block of the plurality of blocks in sequence; and
read a second word line of the block after reading each first word line of the plurality of blocks.

7. The memory system of claim 1, wherein the processing circuitry is further configured to cause the memory system to:
perform, in response to powering the memory system, a third dummy read operation on each first page of a plurality of blocks of memory cells including the block, wherein each of the memory cells of the block transitions to the first state in accordance with performing the third dummy read operation; and
perform an error scan operation on a subset of blocks of the plurality of blocks after performing the third dummy read operation and prior to performing the first dummy read operation.

8. The memory system of claim 1, wherein the processing circuitry is further configured to cause the memory system to:
detect one or more trigger conditions for reducing dummy read operations; and
refrain from performing a third dummy read operation on the block in response to detecting the one or more trigger conditions.

9. The memory system of claim 1, wherein the memory cells comprise non-volatile memory cells, each non-volatile memory cell associated with one of a plurality of logical pages that includes the first page.

10. A non-transitory computer-readable medium storing code comprising instructions which, when executed by processing circuitry of a memory system, cause the memory system to:
perform a first dummy read operation on a block of memory cells, wherein the memory cells of the block transition to a first state in accordance with performing the first dummy read operation;
determine whether a threshold is satisfied in response to performing the first dummy read operation, wherein the threshold comprises a duration after performing the first dummy read operation that the memory cells remain in the first state; and
perform a second dummy read operation on a first page of the block of memory cells in response to determining that the threshold is satisfied, wherein the memory cells remain in the first state in accordance with performing the second dummy read operation.

11. The non-transitory computer-readable medium of claim 10, wherein:
a dummy read operation is associated with reading data from one or more memory cells and refraining from outputting the data; and
a normal read operation is associated with reading data from the one or more memory cells and outputting the data.

12. The non-transitory computer-readable medium of claim 10, wherein:
the first state corresponds to a transient state for which a threshold voltage distribution for one or more memory cells is unshifted relative to a target threshold voltage distribution used for reading the one or more memory cells;
the memory cells of the block are in a second state prior to performing the first dummy read operation; and
the second state corresponds to a stable state for which a threshold voltage distribution for one or more memory cells is shifted relative to the target threshold voltage distribution.

13. The non-transitory computer-readable medium of claim 10, wherein the instructions, when executed by the processing circuitry of the memory system, further cause the memory system to:
determine whether the threshold is satisfied for a second occurrence after performing the second dummy read operation; and
perform a third dummy read operation on the first page of the block in response to determining that the threshold is satisfied for the second occurrence, wherein the memory cells remain in the first state in accordance with performing the third dummy read operation.

14. The non-transitory computer-readable medium of claim 10, wherein the instructions to perform the second dummy read operation, when executed by the processing circuitry of the memory system, further cause the memory system to:
perform the second dummy read operation on a plurality of blocks of memory cells including the block, wherein the memory cells of each block remain in the first state in accordance with performing the second dummy read operation.

15. The non-transitory computer-readable medium of claim 14, wherein the instructions to perform the second dummy read operation on the plurality of blocks, when executed by the processing circuitry of the memory system, further cause the memory system to:
read a first word line of the block;
read, after reading the first word line of the block, a first word line of each other block of the plurality of blocks in sequence; and
read a second word line of the block after reading each first word line of the plurality of blocks.

16. The non-transitory computer-readable medium of claim 10, wherein the instructions, when executed by the processing circuitry of the memory system, further cause the memory system to:
perform, in response to powering the memory system, a third dummy read operation on each first page of a plurality of blocks of memory cells including the block, wherein each of the memory cells of the block transitions to the first state in accordance with performing the third dummy read operation; and
perform an error scan operation on a subset of blocks of the plurality of blocks after performing the third dummy read operation and prior to performing the first dummy read operation.

17. The non-transitory computer-readable medium of claim 10, wherein the instructions, when executed by the processing circuitry of the memory system, further cause the memory system to:
detect one or more trigger conditions for reducing dummy read operations; and
refrain from performing a third dummy read operation on the block in response to detecting the one or more trigger conditions.

18. The non-transitory computer-readable medium of claim 10, wherein the memory cells comprise non-volatile memory cells, each non-volatile memory cell associated with one of a plurality of logical pages that includes the first page.

19. A method by a memory system, comprising:
performing a first dummy read operation on a block of memory cells, wherein the memory cells of the block transition to a first state in accordance with performing the first dummy read operation;
determining whether a threshold is satisfied in response to performing the first dummy read operation, wherein the threshold comprises a duration after performing the first dummy read operation that the memory cells remain in the first state; and
performing a second dummy read operation on a first page of the block of memory cells in response to determining that the threshold is satisfied, wherein the memory cells remain in the first state in accordance with performing the second dummy read operation.

20. The method of claim 19, wherein:
a dummy read operation is associated with reading data from one or more memory cells and refraining from outputting the data; and
a normal read operation is associated with reading data from the one or more memory cells and outputting the data.

21. The method of claim 19, wherein:
the first state corresponds to a transient state for which a threshold voltage distribution for one or more memory cells is unshifted relative to a target threshold voltage distribution used for reading the one or more memory cells;
the memory cells of the block are in a second state prior to performing the first dummy read operation; and
the second state corresponds to a stable state for which a threshold voltage distribution for one or more memory cells is shifted relative to the target threshold voltage distribution.

22. The method of claim 19, further comprising:
determining whether the threshold is satisfied for a second occurrence after performing the second dummy read operation; and
performing a third dummy read operation on the first page of the block in response to determining that the threshold is satisfied for the second occurrence, wherein the memory cells remain in the first state in accordance with performing the third dummy read operation.

23. The method of claim 19, wherein performing the second dummy read operation comprises:
performing the second dummy read operation on a plurality of blocks of memory cells including the block, wherein the memory cells of each block remain in the first state in accordance with performing the second dummy read operation.

24. The method of claim 23, wherein performing the second dummy read operation on the plurality of blocks comprises:
reading a first word line of the block;
reading, after reading the first word line of the block, a first word line of each other block of the plurality of blocks in sequence; and
reading a second word line of the block after reading each first word line of the plurality of blocks.

25. The method of claim 19, further comprising:
performing, in response to powering the memory system, a third dummy read operation on each first page of a plurality of blocks of memory cells including the block, wherein each of the memory cells of the block transitions to the first state in accordance with performing the third dummy read operation; and
performing an error scan operation on a subset of blocks of the plurality of blocks after performing the third dummy read operation and prior to performing the first dummy read operation.
